(19) United States
(12) Patent Application Publication
(10) Pub. No.: US 2025/0298721 A1
(43) Pub. Date: Sep. 25, 2025

(54) GENERATIVE AI-BASED TOOL FOR DEBUG

(71) Applicant: Microsoft Technology Licensing, LLC, Redmond, WA (US)

(72) Inventor: Erik William BERG, Portland, OR (US)

(21) Appl. No.: 18/731,139

(22) Filed: May 31, 2024

Related U.S. Application Data
(60) Provisional application No. 63/567,558, filed on Mar. 20, 2024.

(51) Int. Cl. G06F 11/36

(52) U.S. Cl. CPC G06F 11/362

(57) ABSTRACT

Embodiments of the present disclosure include debug tools comprising a generative AI-based tool configured to provide suggested follow up questions during a debug session. The generative AI-based tool is capable of analyzing the current conversation session and providing suggestions for next steps in the debug process. In one embodiment, the generative AI-based tool can automatically select the next step in the debug process and iteratively continue until the problem has been debugged.

### PRIORITY CLAIM

This application claims priority under 35 USC 119(e) to U.S. Provisional Patent Application Ser. No. 63/567,558, filed Mar. 20, 2024, all of which is incorporated herein by reference in their entirety.

### BACKGROUND

The present disclosure relates generally to scalable generative AI-based tool infrastructures and in particular to an application of a scalable generative AI-based tool infrastructure for debug.

Debugging is a critical part of the digital design and integrated circuit design process that ensures the designed system functions as intended by identifying problems such as errors, glitches, and unforeseen issues. These problems can in turn be rectified so that the system functionality is correct. In some instances, problems identified during the verification process can be investigated and the root cause can be determined through the debugging process. The debugging process can be very time intensive and require expert knowledge to troubleshoot problems. As such, there is a need for an improved solution to debug designs.

### BRIEF DESCRIPTION OF THE DRAWINGS

FIG. 1 illustrates verification according to an embodiment.

FIG. 2 illustrates a verification process according to an embodiment.

FIG. 3 illustrates an example formal verification generative AI-based tool graphical user interface according to an embodiment.

FIG. 4 illustrates an example property generator generative AI-based tool graphical user interface according to an embodiment.

FIG. 5 illustrates an example module generator generative AI-based tool graphical user interface according to an embodiment.

FIG. 6 illustrates an example bind module generator generative AI-based tool graphical user interface according to an embodiment.

FIGS. 7A-C illustrate an example configuration parameter generative AI-based tool graphical user interfaces according to an embodiment.

FIG. 8A-C illustrates an example design flow generation generative AI-based tool graphical user interface according to an embodiment.

FIG. 9 illustrates an example test input generation generative AI-based tool graphical user interface according to an embodiment.

FIG. 10 illustrates an example generative AI-based tool architecture according to an embodiment.

FIG. 11 illustrates an example generative AI-based tool generated LLM input according to an embodiment.

FIG. 12 illustrates a flowchart for a generative AI-based tool according to an embodiment.

FIG. 13 depicts a simplified block diagram of an example computer system, which can be used to implement some of the techniques described in the foregoing disclosure.

### DETAILED DESCRIPTION

Described herein are techniques for debug. In the following description, for purposes of explanation, numerous examples and specific details are set forth in order to provide a thorough understanding of some embodiments. Various embodiments as defined by the claims may include some or all of the features in these examples alone or in combination with other features described below and may further include modifications and equivalents of the features and concepts described herein. While verification is described here as one example, it is to be understood by those skilled in the art that the scalable copilot infrastructure described herein has many applications where a copilot may be useful in improving the quality of an LLM's generated responses. A copilot can be designed for generating domain specific code syntax that may not be well understood by LLMs. The scalable generative AI-based tool can also be designed to assist in the debug process by generating responses to questions from an engineer debugging the problem plus the next likely steps that the engineer could take.

Embodiments of the disclosure include a tool that leverages generative artificial intelligence to create portions of a verification testbench syntax and reduce the time and cost of development. In one embodiment, the present disclosure includes a formal verification generative AI-based tool that generates a formal verification testbench for a system Verilog design module. In certain embodiments, various generative AI-based tools may include some or all of the following. For example, the system may include a generative AI-based tool to convert natural language descriptions of assertions to system Verilog assertion syntax. A generative AI-based tool may provide a set of example assertions in a Retrieval Augmented Generation (RAG) process to improve the quality of the generated assertion code. A generative AI-based tool may map the assertion descriptions to the required signals in the Verilog design module. A generative AI-based tool may generate a system Verilog module that contains the generated assertion syntax. A generative AI-based tool may generate the module interface without user guidance. The generated module may have the correct signal declarations based on the signals consumed in the assertion properties. A generated module may have the correct parameter declarations based on the parameters used in the assertion properties. A generative AI-based tool may provide a set of example modules generated from assertions in a RAG process to improve the quality of the generated module code. A generative AI-based tool may generate a system Verilog module to bind the module containing the assertions to the Verilog design module. A generative AI-based tool may provide a set of example bind modules generated from system Verilog modules in a RAG process to improve the quality of the generated module code. A generative AI-based tool may consume the file defining the build flow and provide the user with options for where to include the generated system Verilog property module and the generated system Verilog bind module in the build collateral. A generative AI-based tool may provide an interface for users to specify Verilog design module configurations based on the parameters in the design module Parameters may be discovered by the generative AI-based tool and not explicitly provided by the user. A generative AI-based tool interface may provide the user with the capability to specify desired parameter values for each configuration the user needs to test. Each set of configuration settings may provide a different test instance. A generative AI-based tool may identify clock and reset signals in the Verilog design module and then interview the user to define the correct clock frequency and reset active state. A generative AI-based tool may interview the user for any assumptions or constraints that should be included in an input test file (e.g., a “tcl” test file) and then generate the appropriate syntax. A generative AI-based tool may enable the user to either regenerate or accept generated collateral for some or all steps described above. A generative AI-based tool may enable the user to provide custom RAG collateral for some or all steps described above. The collateral generated by the generative AI-based tool may include: a generated assertion module, a generated bind module, an updated build file, a generated configuration parameter files, a generated input test file (e.g., a “tcl” test files) for various configuration instances, and command (“Cmd”) lines for running the tcl test files formal verification tool, such as the “VC Formal” tool by Synopsys®, for example.

The present disclosure also describes a generative AI-based tool that is capable of predicting the directions that the debug process could follow based on past decisions made by the user. In one example, a user may ask a question to the tool such as “Find my error message.” The tool may in response convert the user request into a data query to extract the debug data from a dataset and returning it to the user. The tool may also leverage a generative AI-based tool to generate follow-up questions that the user may wish to ask as a way of guiding the user through the debug process. In some instances, answers to these follow up questions may also be provided to the user. This additional step of predicting the subsequent questions that the user may wish to ask can be particularly useful to guide users through the debug process, especially for users that are new to the debug process that would benefit from some guidance.

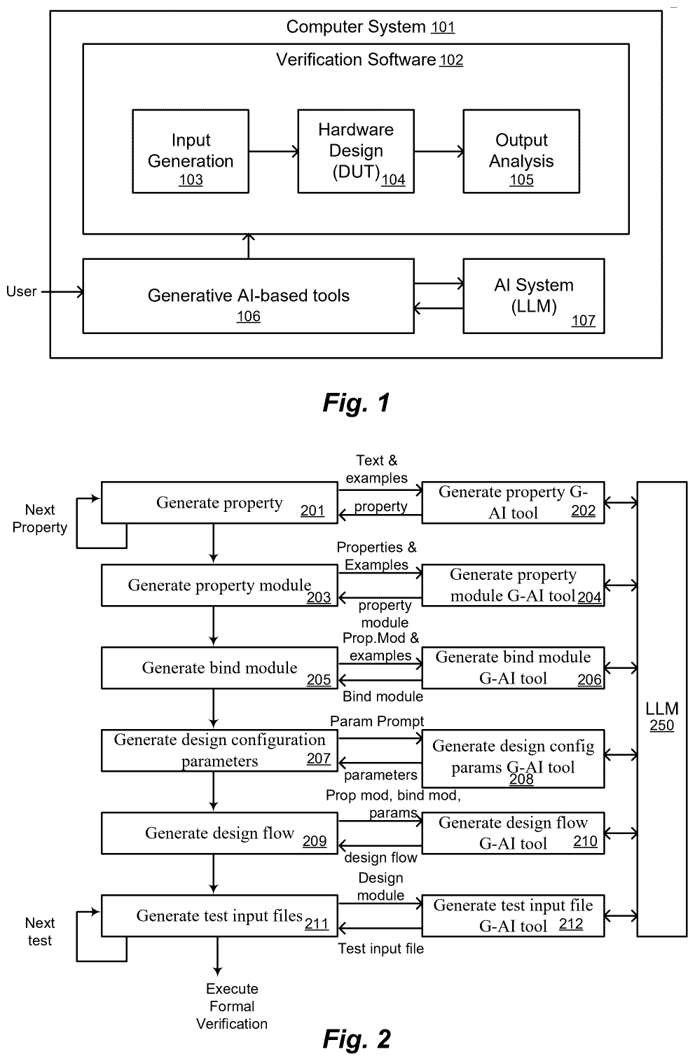

FIG. 1 illustrates a verification system 102 according to an embodiment. Verification software system 102 may execute on a computer system 101, which may include one or more computers, cloud computers, virtual machines or the like that include one or more processors (e.g., central processing units (CPUs) and or customized processors for performing AI functions) and memory (e.g., DRAM, SRAM, non-volatile memory, and the like). Verification software 102 includes a hardware design 104 (aka, a design module or device under test (DUT)), which is a digital representation of a digital circuit being constructed. Verification software 102 includes input generation 103 to generate inputs to design 104 and output analysis 105 to receive outputs generated by design 104 and determine if the outputs conform to the desired functionality and/or specification, for example. In various embodiments described herein, verification software 102 interacts with one or more generative AI-based tools 106 as described in more detail below. In various embodiments, generative AI-based tools 106 may generate customized inputs 110 (aka, prompts) to an artificial intelligence (AI) system 107. AI system may be a large language model (LLM), for example, configured to perform generative AI functions such as publicly available generative AI from GPT-4 by OpenAI®, for example. In other examples, the AI system may be a private LLM, thus providing security and privacy to the data being provided to, and being received from, the LLM. In various embodiments, a user may interact with generative AI-based tool(s) 106 to streamline and automate generation of verification code for verifying a particular design 105, such as input generation 103 and/or output analysis 104, for example. The generative AI-based tool framework includes an index that stores entries containing relevant information for a given programing task or domain. Examples of the relevant information stored in the entries include code snippets, API references, and code examples. The entries may be used as part of the input to the LLM 107 so that the quality of the output of the LLM is improved. While circuit verification is one use case for the generative AI-based tools and the LLM, there are many other applications where a generative AI-based tool in conjunction with an LLM may be able to provide higher quality output in comparison to the LLM alone.

FIG. 2 illustrates a verification process according to an embodiment. As described further below, one embodiment of the present disclosure includes a plurality of customized generative AI-based tools for generating a formal verification system (aka, a testbench) for a particular design module to be tested. As shown here, the formal verification system consists of many different parts to be generated (201, 203, 205, 207, 209, 211) and each part may have its own corresponding syntax. The syntaxes may be different so therefore each part may include its own generative AI-based tool which may be trained specifically the syntax of that part of the formal verification system. Features and advantages of the present disclosure include a “bottom up” methodology, where properties are generated using a property generative AI-based tool 202, a property module is generated using a dedicated property module generative AI-based tool 204, a bind module is generated using a bind module generative AI-based tool 206, design configuration parameters are generated using a design configuration parameters generative AI-based tool 208, a design flow is generated using a design flow generative AI-based tool 210, and test input files are generated using a test input file generative AI-based tool 212. The test files may be executed to perform a formal verification of the design file (DUT), for example.

In certain embodiments, the generative AI-based tools guide a user who may be unfamiliar with the process for generating a formal verification testbench from property generation to the creation of tests quickly and efficiently. Previously this required training, documentation, and many manual steps to complete. The generative AI-based tool may also assist in editing information provided by the user such as commands so that the information is in the proper syntax. These are some of the advantages of the generative AI-based tool infrastructure.

Initially, in one example embodiment, a data object may be created for storing outputs that is visible to all the generative AI-based tool components. This object contains the name of the project consisting of all the generated output, the design module (e.g., the DUT) that the generated content applies to, and the name of the directory where the output collateral will be stored. Each of the steps may include a unique generative AI-based tool that performs unique prompt engineering, for example.

At 201, properties are generated from natural language descriptions provided by the user. These properties may be stored in the data object. Properties are known components of the Verilog design language. Properties may be used to define a property of the circuit under test that must hold true for the circuit to be validated. As a simple example, one property may be that there will never be two (2) reads on consecutive clocks. If you detect two (2) reads on consecutive clocks, the circuit is not validated.

In some embodiments, comments may be automatically copied from a circuit specification document (e.g., assertions, or things about the design that are intended to be true), and the comments may be input to an LLM to generate properties having the correct syntax. Generate property generative AI-based tool 202 may be configured to generate a custom script comprising a textual description of the property to be generated, together with one or more examples of textual descriptions and corresponding correct property syntax, for example. Accordingly, generate property generative AI-based tool 202 may generate properties for a piece of design code from the natural language description of property (e.g., a comment from the specification) and pieces of example text and corresponding example code in the prompt to an LLM 250. LLM 250 generates individual properties corresponding to the textual descriptions and conforming to the property syntax provided with the text. A user may repeat this process for multiple properties used to verify the DUT, for example.

Once the individual properties are autogenerated, a property module may be generated at 203. A property module includes, for example, user-defined combinations of generated properties. The property module may comprise one or both of assumes (formal verification inputs) or asserts (formal verification outputs). Selected properties generated at 201 may be input into LLM 250 to create a complete properties module, which may comprise module syntax and signal properties such as signal logic and/or parameter logic (e.g., bus or register widths, register settings, flags, and the like). Accordingly, properties module generative AI-based tool 204 may be configured to receive properties generated at 201, together with example properties and correct syntax for corresponding example property modules. Generate property module generative AI-based tool 204 may be configured to build a custom property module prompt, which is sent to LLM 250. LLM 250 autogenerates a property module comprising the properties generated at 201 and code for implementing the properties in a test bench, for example. In one embodiment, the generated property module from LLM 250 may be written to a file in an output directory specified in the data object or added to the data object mentioned above (or both), for example.

Next, at 205, a bind module is generated. A bind module connects the property module to the design module, for example. The bind module may include user-defined combinations of generated property modules (e.g., which may be stored in the data object). Once binding is performed, property modules may be attached to the design module, and once attached, may feed signals from the design module into the property module, for example. The properties module, in turn, determines if any properties are being violated. Binding 205 may include sending one or more property modules and examples of property modules and correct binding modules to bind module generative AI-based tool 206, for example. Generative AI-based tool 206 generates a bind module for the input property module(s) conforming to the examples. The generated bind module may be written to a file in the output directory specified in the data object or added to the data object (or both), for example.

Next, at 207, default configuration parameters for the design module may be specified. In one embodiment, default configuration parameters are retrieved from the design module. These parameters may set values for signals, digital structures, and other aspects of the design and properties. Configuration parameters may define configurations for tests to be run, for example. There may be a one-to-one relation between configurations and input test files generated. In some embodiments, configuration parameters may change the design architecture on the fly during the design and verification process, for example. Generative AI-based tool 208 may be configured to receive a natural language query, Verilog and system Verilog design modules, Verilog and system Verilog design code snippets, code snippets from other non-Verilog languages, customized instructions to the LLM, error messages from log files, signal structure description. LLM 250 may be used to read the design module and extract out the parameter names and default values. For example, generative AI-based tool 208 may construct a prompt to LLM 250 and produces functional code satisfying the natural language query. This may include new generated code and/or repairs to existing code supplied as part of the prompt. In one embodiment, parameters for the design module are specified in the data object and read by the LLM and presented in a GUI window to the user. The user can then create new configurations and store them in the data object with user-defined labels.

Next, at 209, a design flow is generated. The design flow, which is also referred to as a build recipe (e.g. a “compile.yml”), is a file that contains the build recipe for the design under test (DUT). Design flow generative AI-based tool 210 is configured to read a design flow file and allows the user to choose which parts of the build flow will include the generated property modules and generated bind modules. A compile.yml file may then be saved by the verification software tool, for example. In some embodiments, the design flow may be a simple script such as a python script and therefore, may not connect to a generative AI-based tool.

Test input files are generated at 211. An example test input file is a “tcl” file, which is the test that the verification system will run that will employ all the information generated at steps 201-210 above. A generate test input file generative AI-based tool 212 may read in clocks and reset signals from the design module specified in the data object, for example, and allow the user to do the following: choose which reset signals will be used in the test, choose active high or active low for reset signals, choose the clock or clocks that will be used in the test, and choose the frequency of the clock or clocks that will be used in the test, for example. Generative AI-based tool 212 may present these items and a user may specify clocks, frequencies, and reset signals (active high or low). In one embodiment, LLM 250 may identify clock signals and reset signals for generate test input file generative AI-based tool 212. In another embodiment, LLM 250 may provide available parameters to generate test input file generative AI-based tool 212. Generative AI-based tool 212 constructs a test input file (e.g., each tcl file is a test) for each configuration specified by the user employing the generated bind module specified by the user and may create a README file that defines the command line to run every generated test, for example. In one embodiment, the test input file may contain a script that is going to be consumed by the formal verification tool.

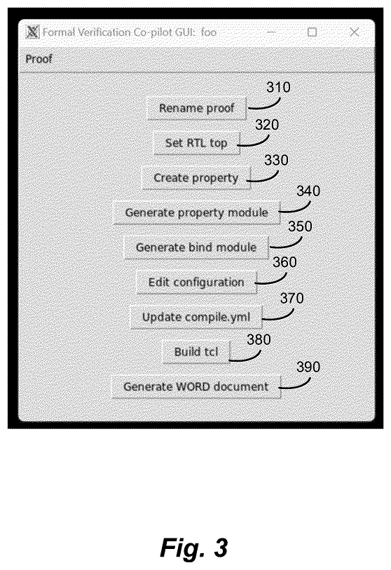

FIG. 3 illustrates an example formal verification generative AI-based tool graphical user interface (GUI) according to an embodiment. The GUI may be presented to a user to guide the user through the process of generating a script to be read by the formal verification tool. This may be particularly useful for users who are not as experienced with the formal verification workflow. The GUI includes a button 310 to “rename proof” (e.g., allowing a user to change the default naming convention for generated files) and a button 320 to “set RTL top” (e.g., to set the context for the LLM by choosing the design code that formal verification assertions will be written for). GUI also includes button 330 to “create property” which is created in the context of RTL top. In one example clicking button 330 may execute generate property 201 in FIG. 2. GUI also includes button 340 to “generate property module.” The property module may be generated based on the created properties in the step above. In one example clicking button 340 may execute property module 203 in FIG. 2. GUI also includes button 350 to “generate bind module” which generates syntax to bind the generated module from above to RTL top and to connect signals across the interface. In one example clicking button 350 may execute generate bind module 205 in FIG. 2. GUI also includes button 360 to “edit configuration.” Edit configuration allows the user to set parameter values for different configurations. For example, the user may want to run the proof for minimum specified FIFO depth, FIFO depth powers of two, and maximum specified FIFO depth to name a few. In one example clicking button 360 may execute generate design configuration parameters 207 in FIG. 2. GUI also includes button 370 to “update compile.yml” which adds the generated property modules and bind modules into the build flow. In one example, clicking button 270 may execute generate design flow 209 in FIG. 2. GUI also includes button 380 to “build tcl file” which is the script that is going to be consumed by the formal verification tool. In one example, clicking button 380 may execute generate test input files 211 in FIG. 2. GUI also includes button 390 which generates a Word document as described above when the button is clicked.

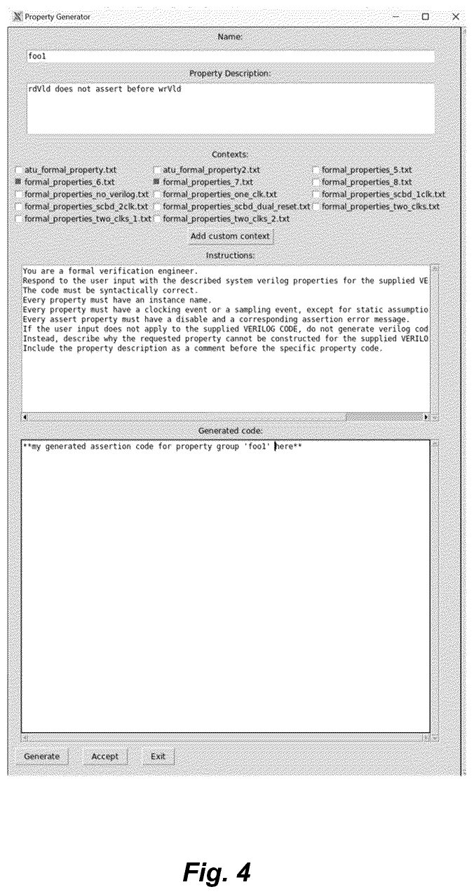

FIG. 4 illustrates an example property generator generative AI-based tool graphical user interface according to an embodiment. This GUI may be a part of generate property generative AI-based tool 202 in FIG. 2. This GUI includes a property name, description of the property, and user selected contexts (example properties) provided as example inputs to the LLM to produce an accurate output. The GUI further includes instructions to the user and a field for the autogenerated properties output by the LLM, for example. The formal verification property generation generative AI-based tool of FIG. 4 includes property group name text window. Text entered in the name window may be used to tag the rest of the content inside a data object, for example. The property description text window comprises text describing the property or properties to be generated. Contexts in this example comprise a set of files that were written to provide example code as part of the prompt to improve the results generated by the LLM. The user may choose which files to include in the prompt based on the syntax that the user wanted to get back from the LLM, for example. The instructions text window may include instructions given to the LLM that define its role and the structure and syntax of the desired response. This is prepopulated by the generative AI-based tool author but can be edited by the user. Generated code text window includes the response from the LLM for the query. This may be editable before it is added to the data object because the user may want to tweak the response from the LLM to fix any syntax or style issues. The “Generate” button, when selected, sends the query to the LLM. The query is constructed from the property description, selected contexts, and the instructions. The “Accept” button may commit the generated code to the data object, for example. An “Exit” button may be used to exit the property generation GUI. In some embodiments, the GUI may further include additional buttons along the bottom next to the “Generate”, “Accept”, and “Exit” buttons. For example, a “View RAG Entries” button may present entries retrieved from the index of the generative AI-based tool. The entries may be presented in a pop-up window. This may be advantageous because the user would be able to view and provide feedback on the entries retrieved from the index that were used as part of the prompt for the LLM to create the generated code. Feedback may include analyzing the quality of the entries, where poor quality entries may be removed, thereby improving the performance of the index over time. As another example, a “Update Index” button may be used to commit new entries stored in blob storage to the index so that they are accessible in future queries. In one embodiment, new entries are automatically committed to the index whenever the accept button is selected, signifying that the user has accepted the generated code. In another embodiment, new entries are stored in blob storage when the accept button is selected. A batch of new entries may be committed to the index when the “Update Index” button is selected. This may be useful in implementations where updating the index every time generate code is accepted is not practical. For purposes of scalability and consistency, the bottom portion of the GUI starting from “Generated code” text may be consistent in the GUI of all generative AI-based tools. This may be advantageous as it creates a uniform look and feel to the GUI. The top portion of the GUI that is above “Generated code” text may be configurable for each generative AI-based tool. The windows and fields present in the top portion may be dependent on the data sources that are being provided as input for a particular generative AI-based tool. For example, the property name, description of the property, user selected contexts, and instructions to the user may be specific to property generator generative AI-based tool.

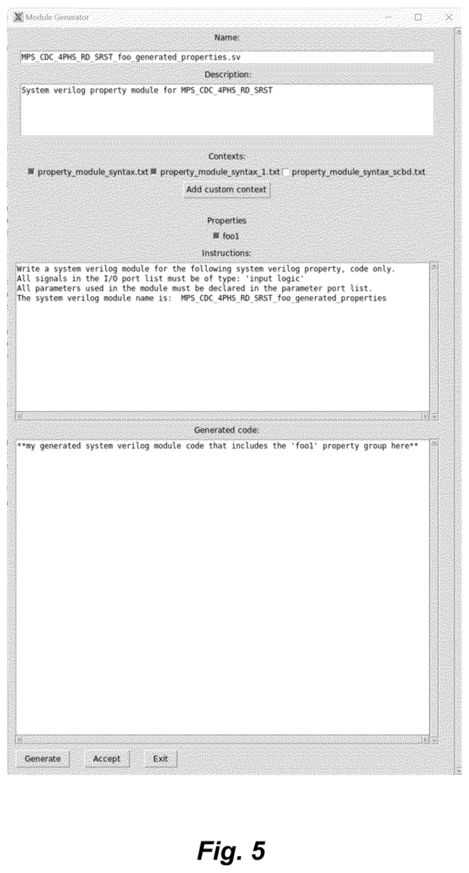

FIG. 5 illustrates an example module generator generative AI-based tool graphical user interface according to an embodiment. This GUI may be a part of generate property module generative AI-based tool 204 in FIG. 2. This GUI includes a name of the property module to be generated, a description of the property module, and user selected context (example property modules) as well as instructions to the user. These fields above the “Generate code” text may be specific to the module generator generative AI-based tool. This generative AI-based tool automatically is configured to receive the properties generated by the GUI in FIG. 4. Generated property module code is output in the generated code portion of the GUI, for example. More particularly, the formal verification module generation generative AI-based tool illustrated in FIG. 5 consists of the following features. The module name text window the name of the module to be generated. The properties comprise the generated properties currently available (e.g., in the data object). The user can choose any or all of the properties to include in the generated module. The instructions text window comprises instructions given to the LLM that define its role and the structure and syntax of the desired response. This is prepopulated by the generative AI-based tool author but can be edited by the user. The generated code text window comprises the response from the LLM for the query. This is editable before it is added to the data object or written to a file because the user may want to tweak the response from the LLM to fix any syntax or style issues. The “Generate” button sends the query to the LLM. The query is constructed from the module name, selected properties, and the instructions. The “Accept” button commits the generated code to the data object and writes the module to a file. The “Exit” button exits the property module generation GUI. As mentioned above, appearance of the bottom portion of the GUI starting with the “Generate code” text may be consistent across all GUIs for the generative AI-based tools.

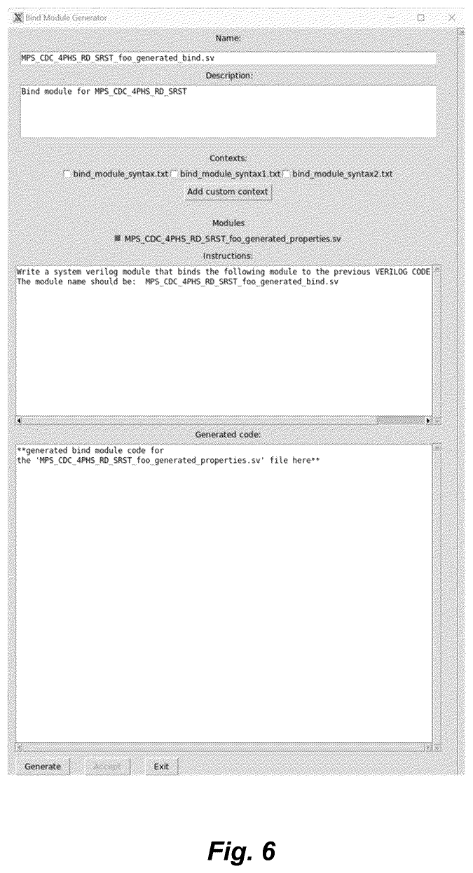

FIG. 6 illustrates an example bind module generator generative AI-based tool graphical user interface according to an embodiment. This GUI may be a part of bind module generative AI-based tool 206 in FIG. 2. This GUI includes a name of the bind module, a description of the bind module, user selected context (example bind modules), and instructions. This generative AI-based tool automatically is configured to receive the property module generated by the GUI in FIG. 5. This GUI includes an output window for generated bind module code. In this example, the formal verification bind module generation generative AI-based tool consists of the following features. A bind module name text window contains the name of the bind module to be generated. Modules includes the generated modules (e.g., currently in the data object). The user can choose any or all of the modules to include in the generated bind module. An instructions text window includes instructions given to the LLM that define its role and the structure and syntax of the desired response. This is prepopulated by the generative AI-based tool author but can be edited by the user. The generated code text window comprises the response from the LLM for the query. This is editable before it is added to the data object or written to a file because the user may want to tweak the response from the LLM to fix any syntax or style issues. The “Generate” button sends the query to the LLM. The query is constructed from the bind module name, selected modules, and the instructions. The “Accept” button commits the generated code to the data object and writes the bind module to a file. The “Exit” button exits the bind generation GUI. As mentioned above, appearance of the bottom portion of the GUI starting with the “Generate code” text may be consistent across all GUIs for the generative AI-based tools.

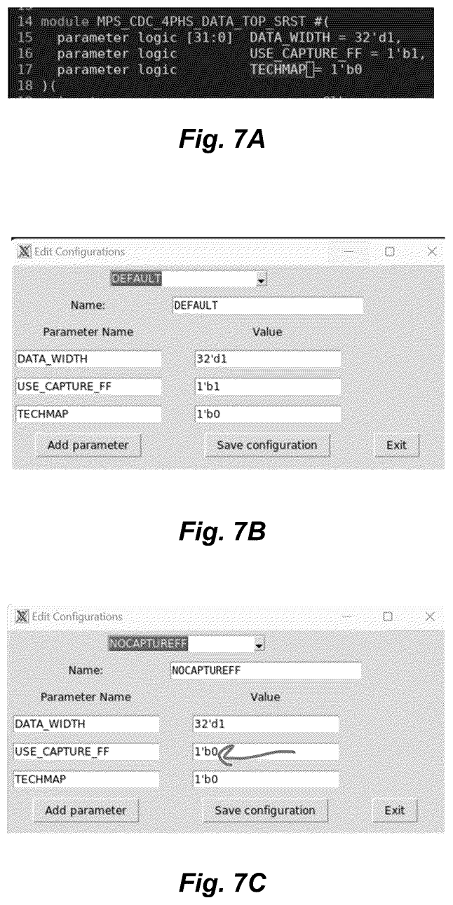

FIGS. 7A-C illustrate an example configuration parameter generative AI-based tool graphical user interfaces according to an embodiment. This GUI may be a part of generate design config params generative AI-based tool 208 in FIG. 2. The design configuration parameter (e.g., ‘Edit Configuration’) generative AI-based tool consists of the following features. The LLM reads the interface parameters for the design module, which may be identified in the data object, and presents them to the user in an editable window. The user can specify new configuration values and save them under a name, e.g., “CONFIG1”. The user can save as many permutations of configurations as they want.

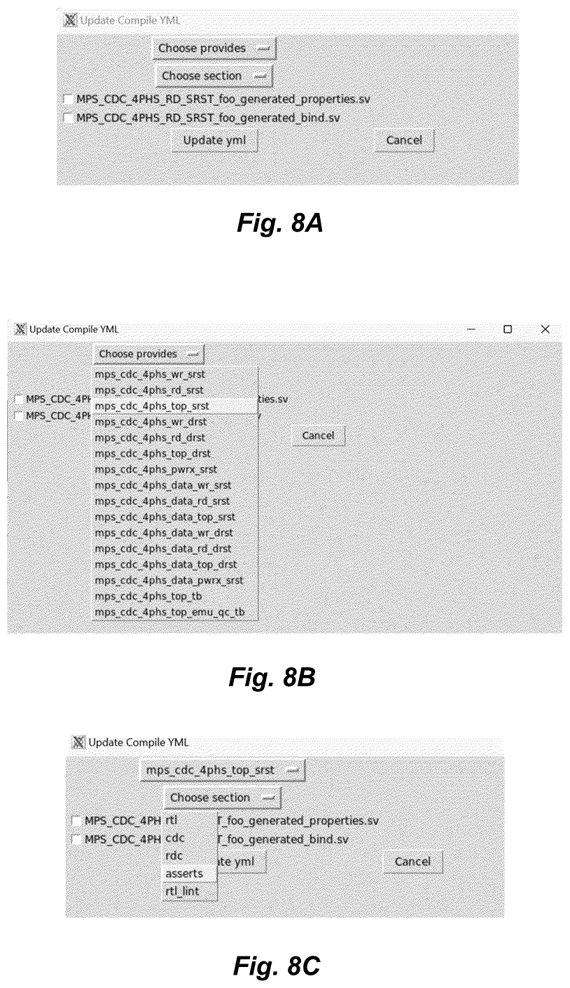

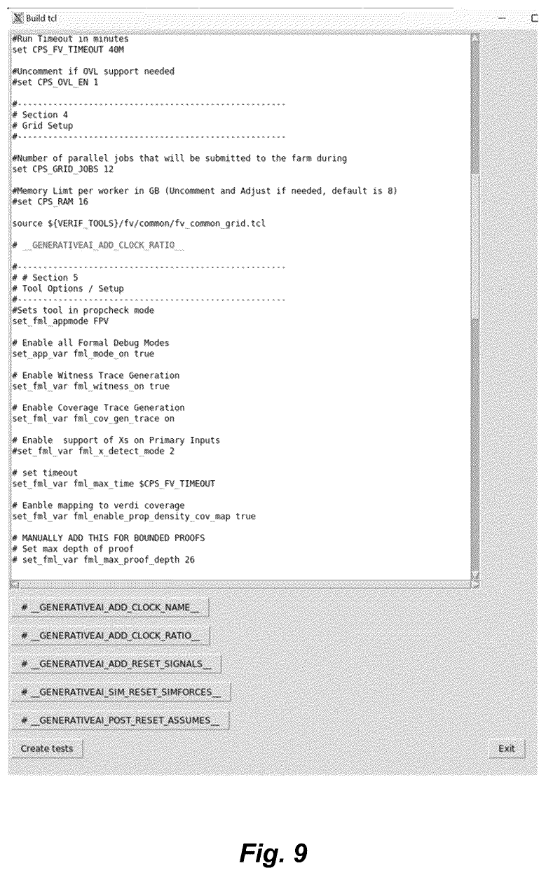

FIGS. 8A-C illustrates an example design flow generative AI-based tool graphical user interface according to an embodiment. This GUI may be a part of generate design flow generative AI-based tool 206 in FIG. 2. In this example, an ‘Update compile.yml’ generative AI-based tool is a python script with no LLM usage. Therefore, the design flow generative AI-based tool is not connected to an LLM. The compile.yml file is the build recipe for the design and verification collateral. The script does the following: First, the compile.yml is read and provides the user with the available options for where the generated collateral can be included in the build flow. After the user chooses the location in the compile.yml where the generated collateral will be integrated into the build flow, the file is saved and the script ends.

FIG. 9 illustrates an example test input generation generative AI-based tool graphical user interface according to an embodiment. This GUI may be a part of generate test input file generative AI-based tool 212 in FIG. 2. In this example, a “Build tcl” generative AI-based tool is the final part of the tool that combines all the other components into the executable test collateral. The LLM reads a tcl template file that has placeholders for the clock, reset, and bind module information that needs to be defined for the test. The “Create tests” button generates a new tcl file that conforms to the user's selections. One (1) tcl file may be generated for each configuration created by the user—e.g., each “Edit Configuration” window above. Tcl files, when executed, compile the design with the above parameter values and collateral specified in build recipe and runs the formal verification engine to see if the properties can be falsified for a given design.

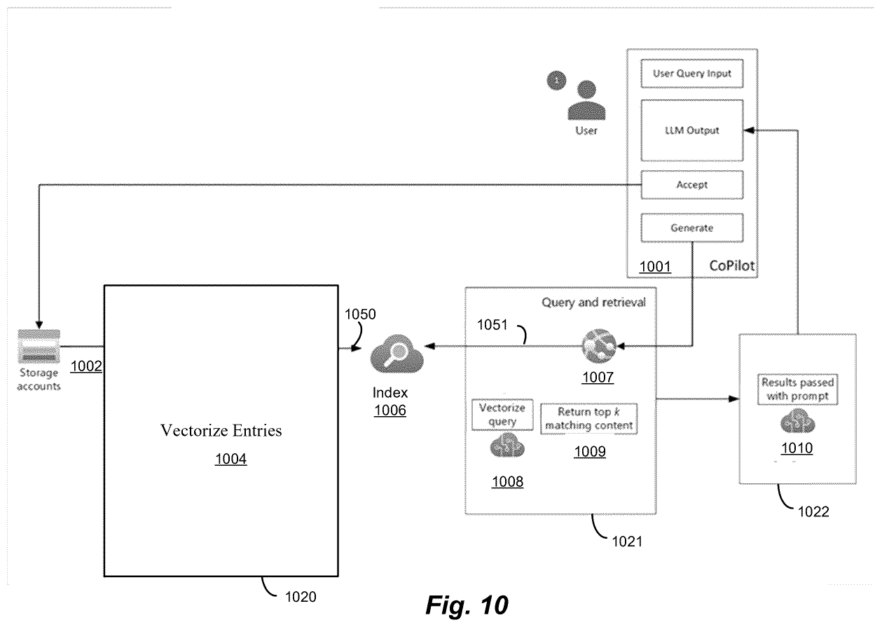

FIG. 10 illustrates an example generative AI-based tool architecture according to an embodiment. In some embodiments the formal verification techniques described above, as well as other verification techniques, may use the following described generative AI-based tool architecture approach to improve the quality of LLM generated responses. Embodiments of the generative AI-based tool architecture described below may be designed for generating domain specific code syntax that is not well understood by traditional LLMs (e.g., functional coverage, formal verification, RTL assertions, DV LINT, and SKILL syntax). It is to be understood by those skilled in the art that the generative AI-based tool architecture approach described can also be used in many other applications to improve the quality of LLM generated responses, especially in applications where the LLM is not familiar with the code syntax desired in the LLM responses.

Embodiments of the present disclosure may include a retrieval augmented generation (RAG) framework that combines an LLM and an index. As illustrated in FIG. 10, the RAG system includes generative AI-based tool 1001, which sends the data that will be used for the RAG index lookup, an embeddings creation component 1020, a query and retrieval component 1021, and a LLM component 1022. Generative AI-based tool 1001 may receive a user query input, generate a modified query, receive an LLM output, and allow the user to accept or edit the LLM output. Query and retrieval 1021 may include an application service (interface) 1007, an embedding model 1008 (e.g. to generate a vectorized query for the index lookup using the LLM model embeddings). A vector is sent to the index 1006 at 1051. Index lookup occurs and relevant entries are returned from the index in a ranked list at 1009 depending on how closely they match the vector for the query. Query and retrieval 1021 allows generative AI-based tool 1001 to choose the maximum number of entries in the list that in total do not exceed a predefined number of tokens. Here, query and retrieval 1021 returns the top k matching entries. The input query can then be supplemented with the retrieved entries. In one embodiment, entries retrieved are added to the query (a.k.a. the modified query) and sent to the LLM 1022. At 1010, a response from the LLM is sent to the generative AI-based tool where it populates the output window for the user to view. In some examples, this output window is the “Generated code:” window of the generative AI-based tool's GUI. At 1002, a user either accepts the response as is or manually edits it before pressing ‘Accept’ button. All the generative AI-based tool fields are saved to the blob storage 1002 for this generative AI-based tool. At 1004, a vector for the entry is generated and a data object is constructed that contains the vector, date, user, and the query data. This output 1050 is then added to the index 1006. Advantages to storing the query data and the vector containing the LLM output accepted by the user include that the query-output pair can be used to further improve the quality of index 1006 since the index would contain more outputs that were accepted by the user, thereby improving the quality of future queries to index 1006.

The LLM may be a neural network that can generate natural language text based on a given input, such as a query or a prompt. An index is a collection of code snippets or documents that contain relevant information for a given programming task or domain, such as API references or code examples.

The index is used as a source of additional context and evidence for the LLM, and to integrate the retrieval and generation processes in a seamless way. In various embodiment, a RAG approach may work as follows.

Given an input query, such as a verification specification or a description, the LLM generates an initial representation of the query. The initial LLM generated query is used to retrieve a set of relevant entries from the index. The retrieval can be done using different methods, such as exact match, keyword search, or semantic similarity, for example. The output is evaluated using a scoring function, which takes into account both the quality of the generation and the relevance of the retrieval. The relevant entries may be ranked according to how well they match the input query. The generative AI-based tool infrastructure may choose the maximum number of entries from this list that can fit in a predefined token window. The scoring function can be learned from data, such as test cases or feedback, or predefined using heuristics or rules. The output with the highest score is selected as the final response.

The retrieved entries from the index are then fed back to the LLM as additional context, along with the original query. The LLM uses this augmented input to generate a refined output, such as a code snippet or a function, that incorporates the information from the index.

Using the currently described approach, the LLM can benefit from the additional information stored in the index, and produce more accurate, informative, and coherent code. The current techniques may further enable the LLM to handle a wider range of programming tasks and domains, without requiring extensive fine-tuning or adaptation. The currently described approach may be applied to various types of LLMs, such as autoregressive or autoencoding models, and various types of indices, such as textual or multimodal.

Additionally, the RAG approach described here may help the LLM to follow coding styles, syntax, and conventions that are specific to a programming task or domain, by retrieving and generating code that is consistent with the index. For example, if the index contains code that follows a certain naming convention, indentation style, or documentation format, the LLM can use the retrieved entries as a reference and generate code that matches the same style and format. This can improve the readability, maintainability, and usability of the generated code.

In some embodiments, the index may be carefully curated, updated, and validated by a user for the specific programming task and domain. The generative AI-based tool infrastructure allows users access to the indexed entries affecting the responses to their prompts so that poor responses can be linked to bad index entries and potentially removed.

RAG, on the other hand, does not modify the parameters of the LLM, but rather augments the LLMs input with external knowledge sources. RAG can enhance the capabilities of the LLM without compromising its generality or diversity, and it can leverage unlabeled or weakly labeled data, such as web pages or code repositories, which are more abundant and accessible than labeled data. RAG may be cheaper to deploy and allows the generative AI-based tool infrastructure to leverage individual indices for domain-specific tasks.

In one example implementation, a scalable generative AI-based tool architecture may include a GUI frontend built from a class-based, widgetized code structure. A portion of the GUI comprised of the “Generated code” window and the buttons at the bottom may, in some example embodiments, be standard for generative AI-based tools, and may contain the connections into the RAG infrastructure. The top portion of the GUI may be customizable based on the data provided by the user to build their query.

A default generative AI-based tool GUI has the following features divided into user customizable and default collateral. User customizable fields include:
Description (query) entry: users can type in natural language what they want the LLM to generate as code.
Custom context button: creates popup window where users can provide additional information or constraints for the query, such as struct definitions or variables.
Edit instructions button: creates popup window where users can adjust the default query instructions that are sent to the LLM.

Default components may include:
Generated code section: users can see the output of the LLM in response to the query. The generated code section is editable, so users can modify the code as they wish before accepting it.
Accept button: users confirm that they are satisfied with the text in the generated code section and add it to the blob storage that supplies the entries for the index.
View RAG Entries button: creates popup window where users can [view] the entries from the index that were retrieved during the RAG flow and used as part of the prompt for the generated code.
Update Index button: add all new entries in the blob storage to the index so that they are accessible in future queries.

As mentioned above, an advantageous approach to generative AI may be achieved through a bottoms-up approach where the user deconstructs a problem into the component parts, asks the AI to solve each component and then asks the AI to synthesize the component solutions into a larger solution. The facilitate this, the generative AI-based tool architecture can be used to build a generative AI-based tool of generative AI-based tools. This approach may be leveraged by the Coverage and Formal Verification generative AI-based tools, as examples. For instance, the task of building coverage collateral is staged to use generative AI to build (1) individual covergroups and coverpoints, (2) coverage modules composed of the covergroups and coverpoints, and then (3) bind modules to connect the coverage modules to the design. The cover property, coverage module, and bind module generative AI-based tools each query and contribute to separate indexes that are specific to their syntax requirements. A similar approach may be used in the Formal Verification generative AI-based tool described above, for example. The formal property generative AI-based tool and the coverage property generative AI-based tool may use the same code except that the default instructions are different, and they use separate index data for code generation. The property module and bind module generative AI-based tools may include the same code base and the same index data as the Coverage generative AI-based tool.

The following describes an example process for creating an index from existing collateral. It will explain how to select, format, and upload the collateral, how to specify the metadata and keywords for the index, and how to test and validate the index.

First, an example field structure of the index for the RAG is described. For instance, each document in the index has the following fields:
Query: The natural language prompt that the user gives to the LLM as input. It describes the collateral that the user wants the LLM to generate. For the coverage generative AI-based tool, the description field would have the description of a cover property for a testplan entry. For the formal verification generative AI-based tool, the description would be for an assert property pertaining to an RTL module.
Context: The optional extra information that the user can provide, such as code snippets, signal struct definitions, or background knowledge, to help the LLM generate more accurate and relevant responses.
Instructions: Used to give the LLM a role, how best to complete that role and any other expectations the user has about the style, format, or completeness of the response. There are default instructions for each generative AI-based tool that the user can override or modify with the “Edit instructions” button.
Module: The Verilog module that the query:response belongs to. Depending on the generative AI-based tool, the module code may be provided as part of the prompt to help the LLM create a better response.
Generated_response: The generated code response that the LLM generates based on the query, context, and instructions.
Accepted_response: The response that the user accepts as correct or satisfactory for their programming task or domain. It can be the same as the generated_response, or it can be modified, corrected, or improved by the user.
Contributor: The employee ID of the person who contributed the entry in the index, used to track the source and quality of the index collateral.
Id: The unique identifier of the document in the index. It can help the user to access, update, or delete the index entry. This entry is generated when the collateral is accepted.

When a new generative AI-based tool is created, the user can choose which of these fields or combinations of these fields are used as part of the index lookup. This gives the user flexibility and control over how the RAG infrastructure searches for the best matching documents in the index. In this example generative AI-based tool architecture, the default fields for index lookup are “query” and “context”. The default fields from each entry that are used as part of the prompt engineering process are “instructions”, “context” “query”, and “accepted_response”. Each generative AI-based tool instance can adjust these as desired by the user.

When a new generative AI-based tool is initially created, the index is empty. To quickly create an index so that users can benefit from the RAG infrastructure, existing collateral from other projects may be directly loaded. The generative AI-based tool creator may create query:response pairs that can be entered into the generative AI-based tool and added into the index with the “Accept” button. In some example embodiments, an index with about 30 entries may boost functional and syntactic accuracy of responses from the LLM by about 90%. The size of the index required to provide measurable benefits to the user may be dependent upon how well user queries map to content stored in the index and how much innate domain syntax knowledge the LLM contains.

After initial seeding of the index, new users will receive better responses from the LLM than they would without the RAG system. When LLM responses do not meet user needs for reasons of style, functionality or syntax, the user can either regenerate the response with the current generative AI-based tool settings, edit the generative AI-based tool fields before regenerating, or manually edit the response.

The generative AI process is inherently stochastic so regenerating may yield a different response that may better meet the user's needs. A user may also choose to edit the fields in the generative AI-based tool to give the LLM more detailed information to help generate a better response. For example, when creating functional coverage of signals defined as “structs”, the user may observe that the LLM responses display no knowledge of the “struct” definition. In these instances, the LLM will require knowledge of the struct definition since it is likely not currently available in the index. This information can be added by the user through the “custom context” button on the GUI.

If the response from the LLM is close but not quite what the user desires, the response can be manually edited in the “Generated Code” window. Pressing the “Accept” button will commit the current generative AI-based tool information to the blob storage for the index to make the query:response information available to future users through the RAG architecture. The tool stores both the “generated_response” and the “accepted_response” in the index. These will converge as more users leverage the generative AI-based tool and commit high quality responses to the index.

### Index Usage and Prompt Engineering

This section will explain how the responses from the RAG infrastructure are used in the prompt engineering process and how the information is passed to the LLM. The prompt engineering process is the method of transforming the user input and the index lookup results into a suitable input for the LLM. The goal is to provide the LLM with enough context and guidance to generate high-quality responses that match the user's expectations and needs. This entire process is managed by the generative AI-based tool and requires no user input.

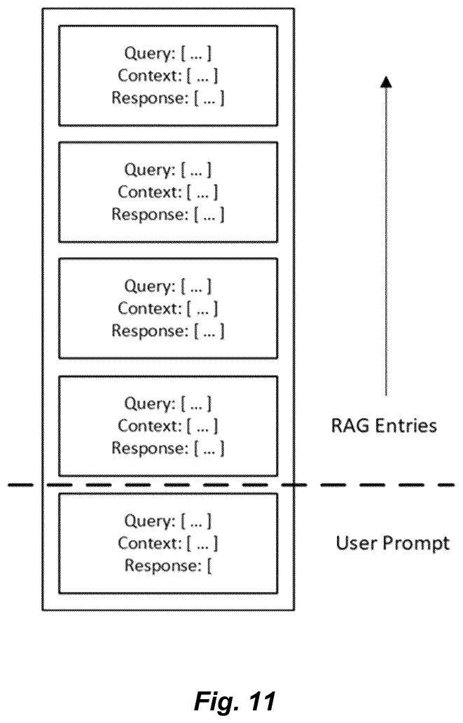

The prompt engineering process consists of the following steps:
1. The user adds the description and any relevant context to the generative AI-based tool and pushes the “Generate” button. The generative AI-based tool constructs the query to the RAG infrastructure based on the fields chosen for that particular generative AI-based tool.
2. The RAG infrastructure performs an index lookup and returns the top k matching index entries from the index. Each index entry contains all the fields previously described in this document, as well as a relevance score indicating how well the index entry matches the user input.
3. The generative AI-based tool infrastructure extracts relevant fields from the index entries and ensures that these selected entries and the rest of the prompt combine to fit within the token window for this LLM model. If the index entries are too large for the allowed token window, the generative AI-based tool will choose the best subset of index entries that fits within the token window. In one embodiment, the best subset of index entries may be selected based on cosine similarity that compares the vectorization of the query with the vectors in the database and returns a sorted list based on the highest value of cosine similarity.
4. The generative AI-based tool constructs a final input for the LLM from the RAG entries and the user's specific query. An example input is shown in FIG. 11.
5. The LLM receives the final input, generates a response and populates the “Generated Code” window. The user can then regenerate or modify the response before accepting it. If the user accepts the response, it is stored in the index with other data scraped from the generative AI-based tool.

In one example implementation, a generative AI-based tool code base is class based and widgetized, allowing users to create new domain-specific syntax generative AI-based tools in minutes that are connected to customized and secure other resources for that generative AI-based tool. New tented blob storage and indices are generated on-demand by new generative AI-based tool deployments.

The generative AI-based tools provide the following benefits to design and verification teams.
1. Remove mundane, tedious, repetitive work to allow engineers to focus on the harder and more interesting engineering problems.
2. Remove the burden of syntax much like compiler removed the burden of machine language to allow people to code in more abstract languages.
3. Give users access to expert knowledge in diverse domains.

The output of the generative AI-based tools improves continuously as users use them and contribute more information into the supporting data index. A description of the index fields and how to start creating a new one is included.

### Generative AI-Based Tools for Debug

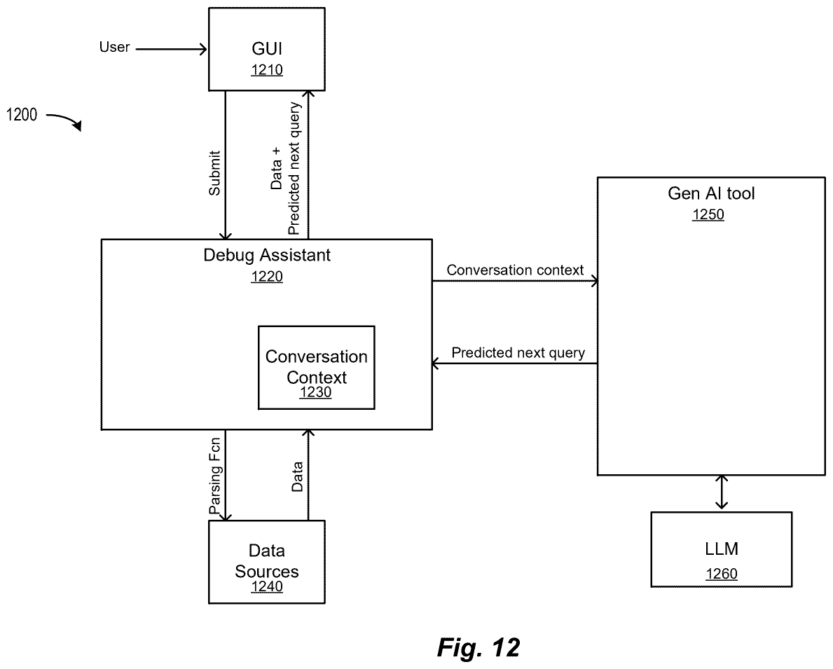

This section covered by FIGS. 12-16 will explain how generative AI-based tools can be utilized for debug by providing recommended next steps to a user. The RAG infrastructure can be configured to analyze the conversation context which includes questions asked so far by the user during the present conversation session and to generate a predicted follow up question or questions that the user may wish to ask to continue the debug process. Advantages of generating predicted follow up questions include guiding a user who is less familiar with the debug process. Advantages also include the ability to have the debut tool automatically debug an error by iteratively predicting follow up questions and automatically asking the predicted follow up questions with the highest confidence score.

FIG. 12 illustrates an architecture for a debug tool according to an embodiment. A user of the debug tool may be an engineer or other technician tasked with debugging a problem with the system such as an error, issue, or fault, to name a few. A user may submit an input query to the debug tool and receive a response to the input query from the debug tool. The input query may be in the form of a question or a command in natural language to fetch information from one or more data sources within the system. The information includes debug data for debugging the problem. Examples of debug data include the power state of the system, the error message generated, the component that generated the error message, to name a few. Once the user receives a response from the debug tool, the user may submit a follow up inquiry in the form of a follow up question or command. This process may repeat until the user has analyzed sufficient data retrieved from the debug tool to determine the root cause of the error or how to repair the error.

In some embodiments of the present invention, the debug tool may aid the debug process by providing to the user potential follow up questions that may be useful for the user to submit. This may help guide the user, particularly novice users who are less familiar with the debug process and may be unsure what follow up questions to submit. As shown, system 1200 includes GUI 1210, debug assistant 1220, data sources, 1240, generative AI-based tool 1250, and LLM 1260. GUI 1210 provides a graphical user interface, such as a display, that the user can communicate with the debug tool. GUI 1210 may present a plurality of dialog boxes. Some of the dialog boxes may be configured to request information from the user while other dialog boxes may be configured to present information to the user. The requested information may be input queries to retrieve debug data from data sources while the presented information may be responses to the input queries that include the retrieved debug data. As shown, GUI 1210 may receive an input query from the user in the form of a question submitted into a user prompt in a dialog box of the graphical user interface. The question may be in natural language and submitted by the user (person debugging the problem) seeking information to help debug the problem in the system. The question may be transmitted to debug assistant 1220 as a submit.

Debug assistant 1220 is configured to perform two functions. The first function is to retrieve the debug data or information requested in the submit from data sources 1240. The second function is to analyze the submit in the context of all the submits from the user in this conversation session and recommend the next follow up question to submit based on the analysis. A conversation session may include all of the input queries submitted to the debug tool that are related to the problem being debugged and the corresponding responses generated by the debug tool. In one embodiment, the conversation session is bound by the context of the current debug problem. For example, a user debugging a problem may begin a debug session by submitting a first input query to the debug tool. This first input query would be saved as part of the conversation session. Based on the response received from the debug tool, the user may follow up with a second input query to dive deeper into the debug process. For instance, the first input query may be “What is the error message?” Once the user knows the error message, a follow up input query may be “Which component generated the error message?” or “What was the power state when the error message was generated?” This process of asking questions related to a problem and receiving answers may be considered the conversation session. The input queries and the corresponding responses related to a conversation session may be stored in conversation context 1230. Once the conversation session is over, conversation context 1230 may be transmitted to generative SI-based tool 1250 to be stored in a vectorized database and then may be deleted in debug assistant 1220 so that it is ready to store queries and corresponding responses related to the next conversation session. In one embodiment, conversation context 1230 stores information about a single conversation session at a time. As shown here, debug assistant 1220 receives a submit (i.e., input query) from GUI 1210. Debug assistant 1220 may convert the submit into a data query to retrieve debug data. For example, a submit having a question “What is my error message?” may be converted into a data query for the error message. Once the desired debug data is known, debug assistant 1220 can determine which data source from data sources 1240 contains the debug data. Debug assistant 1220 may then generate a parsing function to retrieve the debug data from the data source. For example, if the debug data is an error message, debug assistant 1220 may understand that error messages are stored in the sim log file and generate a parsing function to retrieve the error message from the sim log file. As another example if the debug data is a PCIe transaction, debug assistant 1220 may understand that PCIe transactions are stored in the PCIe log file and generate a parsing function to retrieve the error message from the PCIe log file. As shown here, debug assistant 1220 may generate a parsing function that is transmitted to the data source associated with the debug data and then receive the debug data.

As mentioned above, debug assistant 1220 may also be configured to generate a predicted next query as a suggestion to the user. The predicted next query may be generated with the aid of generative AI-based tool 1250. Generative AI-based tool 1250 may pass the conversation context 1230 to generative AI-based tool 1250. In one embodiment, the entire conversation context 1230 is passed to generative AI-based tool 1250. In another embodiment, a portion of the conversation context 1230 is passed to generative AI-based tool 1250. The benefits of passing only a portion is efficiency but passing the entire conversation context 1230 may provide more accurate results in the predicted next query or queries. When only a portion of the conversation context is transmitted from debug assistant 1220 to generative AI-based tool 1250, it could be the portion that is more relevant to the current input query submitted. For example, if five input queries have already been submitted in the conversation session and we are currently on the sixth input query submitted, the fourth, fifth, and sixth input queries may be transmitted as the portion since the fourth and fifth input query are temporally closer to the current sixth input query. In this example, the portion is defined as the two input queries (and responses) prior to the current input query but in other examples, the portion can be defined as more (or less) input queries and responses.

Generative AI-based tool 1250 in turn may use this information to generate a prompt which is provided to LLM 1260 as input. Generative AI-based tool may also store the conversation context to improve its ability to generate future prompts for the LLM. LLM 1260 generates an output based on the input and the output is returned to debug assistant 1220 as the predicted next query. Debug assistant 1220 may then provide the debug data and the predicted next query to GUI 1210 to present to the user. In some embodiments, the response to the predicted next query may also be generated by debug assistance 1220 and provided to GUI 1210. In some embodiments, the debug data may be passed through a LLM (not shown) to generate a response for the debug data in natural language. For example, if the debug data is “ERROR_ACCESS_DENIED”, passing the debug data through an LLM may result in an output “The error that occurred is that access is denied.” Advantages of passing the debug data through an LLM include that the response provided to the user is in a form that is easier to comprehend. The LLM may be trained with training information for the data sources that maps error messages to their intended meaning in natural language.

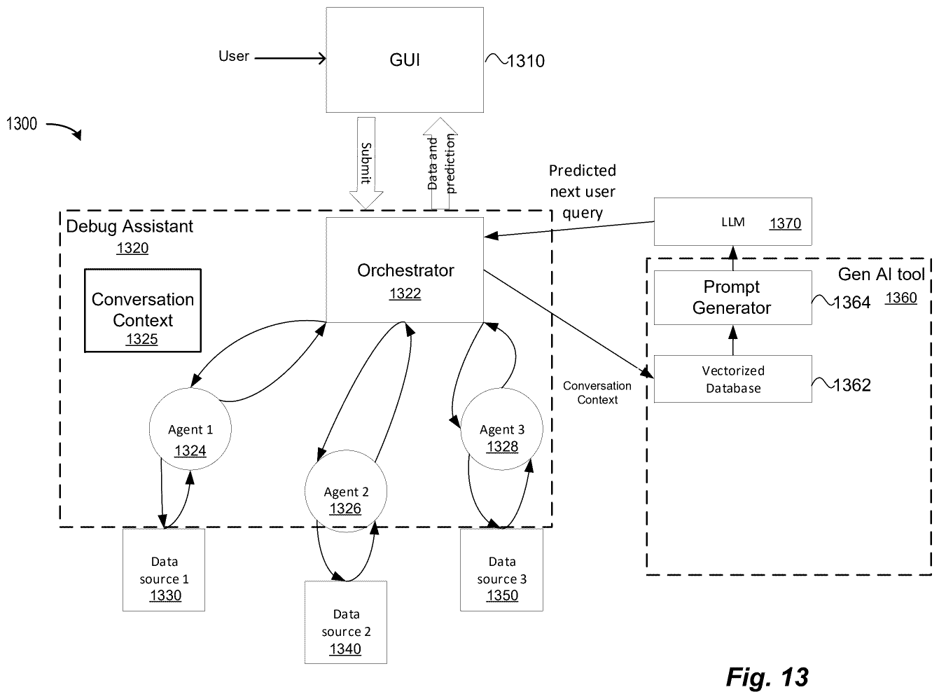

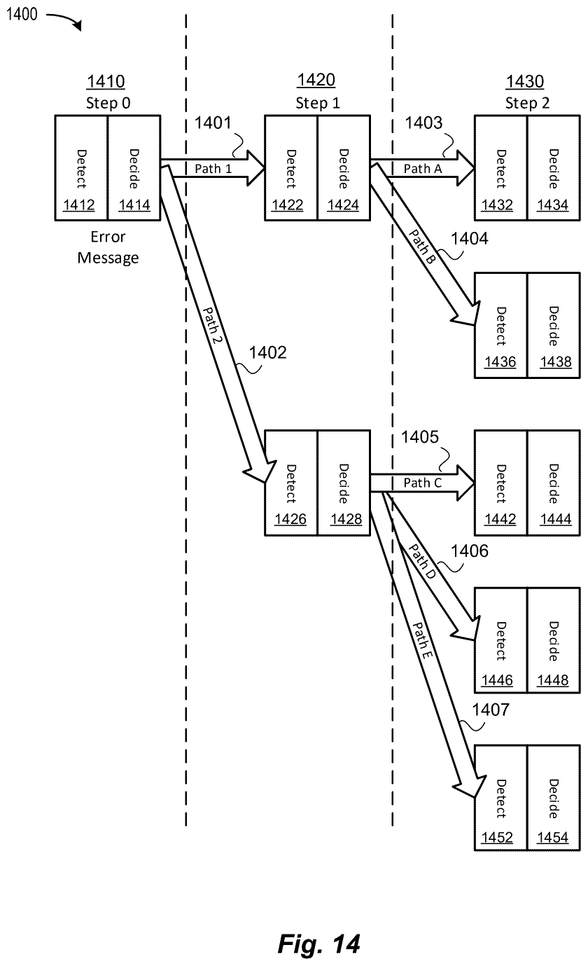

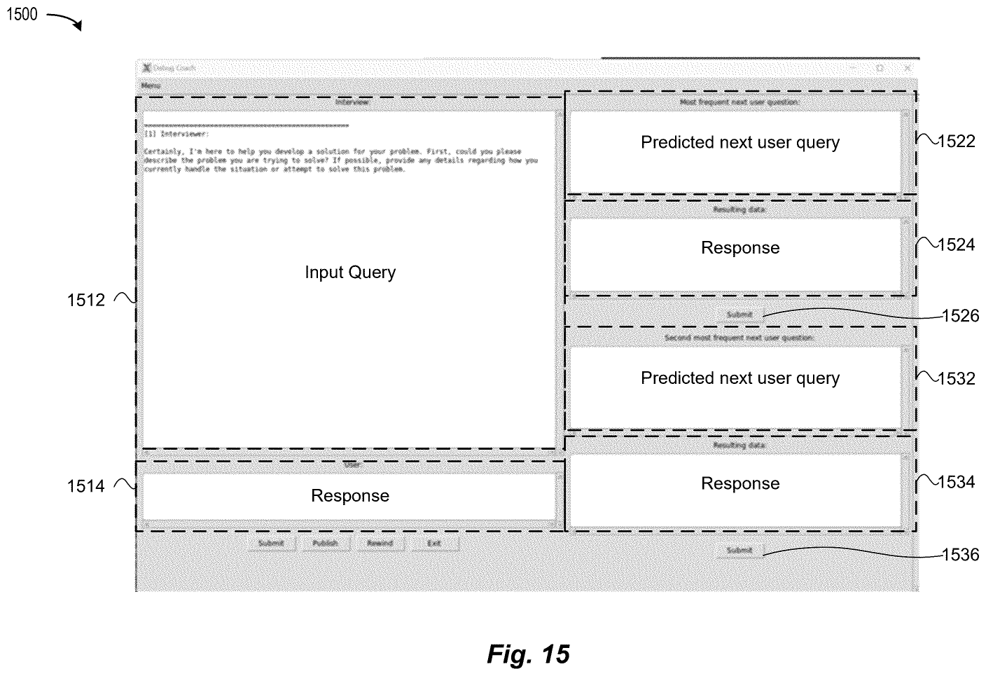

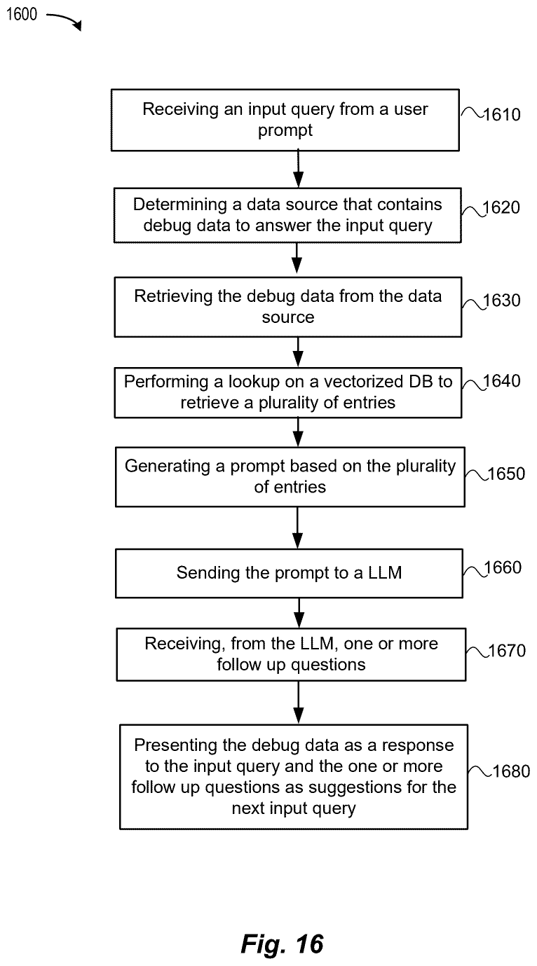

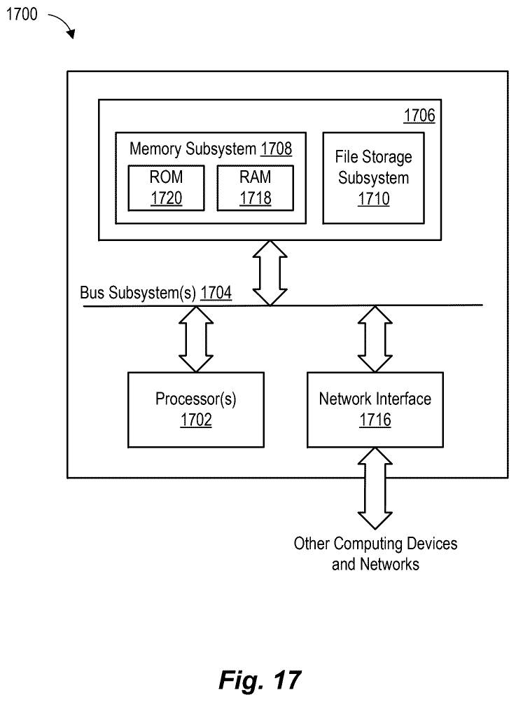

FIG. 13 illustrates an architecture for a debug tool according to another embodiment. As shown, system 1300 is a more detailed architecture of the debug tool described in FIG. 12. System 1300 includes GUI 1310, debug assistant 1320, generative AI-based tool 1360, LLM 1370, and data sources 1330, 1340, and 1350. Debug assistant 1320 includes conversation context 1325, orchestrator 1322, agent 1324, agent 1326, and agent 1328. Orchestrator 1322 is configured to receive a submit from GUI 1310, determine the debug data being requested from the submit, and determine the agent best suited to handle the submit based on the debug data being requested. Orchestrator 1322 may also store the submit (or alternatively the debug data request) in conversation context 1325 as part of the present conversation session. For example, the submit may include the question “What is my error message?” or “Fetch the error message.” while the debug data request (i.e., data query) may simply be “error message.” Orchestrator 1322 may also store the response corresponding to the submit in conversation context 1325 once it has been retrieved from the data source. In some embodiments, orchestrator 1322 may include an LLM (not shown) configured to convert the question into a data query. In one embodiment, orchestrator 1322 may access a look up table (not shown) to identify which data source stores the debug data corresponding to the data query. In another embodiment, orchestrator 1322 may utilize a LLM (not shown) to receive a data query and generate as output the agent to route or assign the data query to.

Each data source may have a different structure and therefore have different techniques to efficiently access the data within the data source. For example, an unstructured log file may include regular expressions and time-stamped unstructured messages. Regular expressions may be used to efficiently access the data within the log file. As another example a table file may include a structure such as columns and formatting. A look up according to the structure may be used to efficiently access the data within the table file. An agent corresponding to the data source may be configured to efficiently access data stored within the data source. As such, each data source has a corresponding agent. As shown here, agents 1324 corresponds to data source 1330, agent 1326 corresponds to data source 1340, and agent 1328 corresponds to data source 1350. Once the data source containing the data query has been identified, orchestrator 1322 may instruct the agent corresponding to the data source to retrieve the debug data. The agent may in turn generate the instructions to retrieve the requested data. In some embodiments, each agent may contain an LLM (not shown) for purposes of refining the data query or for purposes of generating a parsing function to access the data in the corresponding data source.

System 1300 further includes generative AI-based tool 1360. Generative AI-based tool 1360 is configured to predict follow up questions that the user may wish to ask the debug assistant in order to further debug the problem. Generative AI-based tool 1360 includes vectorized database 1362 and prompt generator 1364. Vectorized database 1362 is a database that stores previous conversation sessions. Vectorized database 1362 may receive the conversation context from orchestrator 1322. In one embodiment, the conversation context received can be the conversation context for the present conversation session. In another embodiment, the conversation context received can be a portion of the conversation session, such as the last few questions submitted by the user and the corresponding responses to the questions. The questions and answers transmitted from orchestrator 1322 should provide context to the current input query submitted. An embedding model may generate a vectorized query for the vectorized database 1362 from the present submit, the debug data, and/or the conversation context. The vectorized query may in turn be provided to vectorized database 1362, which returns the top N matches. The top N matches may be the top matches of past conversation sessions stored in vectorized database 1362 that are most similar to the current conversation session. The value for N may be a setting configured in the vectorized database or a setting in the debug assistant. In one embodiment, the past conversation sessions in their entirety are returned from the vectorized database 1362. In another embodiment, a portion of past conversation sessions are returned from vectorized database 1362. For example, when the generative AI-based tool 1360 receives a portion of conversation context 1325 from orchestrator 1322, vectorized database 1362 may also generate top N matches that include a portion of the top N past conversation sessions that are similar to the current conversation session. The portion input to the vectorized database may include the same number of queries and responses as the portion output from the vectorized database.

The portion may be queries and responses that Prompt generator 1364 receives the top N matches along with the current conversation context, submit, and debug data corresponding to the submit to generate a prompt for LLM 1370. The submit and the debug data (and optionally also the conversation context) may be saved in the vectorized database so that future queries can benefit from the question currently being asked by the user. Over time, the vectorized database will include more entries containing conversation sessions and therefore, will be able to provide more timely and relevant suggestions for users.

LLM 1370 receives the prompt and generates an output that includes top M predicted next user queries. The value for M may be a setting configured in LLM 1370, generative AI-based tool 1360, or debug assistant 1320. Alternatively, the value for M may be dynamic in that predicted next user queries having a confidence score above a predefined threshold are provided as part of the output. In other words, LLM 1370 may generate a number of predicted next user queries. A confidence score may be assigned to each predicted next user query by LLM 1370 or a query scoring component (not shown). Predicted next user queries having a confidence score above a predefined threshold may be transmitted to orchestrator 1322. As a result, the number of predicted next user queries included in the generated output may vary. The output from LLM 1370 is returned to orchestrator 1322, which in turn transmits the debug data and the top M predicted next user queries to GUI 1310 to be presented to the user. The debug data and the top M predicted next user queries are presented to the user in natural language so that it is easier for the user to comprehend. The conversion of the debug data into natural language may be performed by the agent or the orchestrator, depending on the implementation details. A LLM (not shown) may assist in the conversion to a natural language statement that is easier for the user to comprehend. Similarly, the conversion of the top M predicted next user queries into natural language may be performed by LLM 1370, generative AI-based tool 1360, or orchestrator 1322. A LLM (not shown) may assist in the conversion to a natural language statement. In one embodiment, LLM 1370's generated output is already in natural language so there is no need for conversion. In some embodiments, vectorized database 1362 is updated to include the current conversation session once the user has completed debugging the problem. Once the user has indicated that the debug of the current problem is complete, orchestrator 1322 may transmit conversation context 1325 to vectorized database 1362 for storage as a new conversation session. This way, vectorized database 1362 is constantly growing and maturing, therefore improving the quality of the top N matches over time.

FIG. 14 illustrates a workflow for debugging a problem according to an embodiment. As shown, workflow 1400 starts with step 1410, followed by step 1420, followed by step 1430. Step 1410 includes two substeps—detect 1412 and decide 1414. In detect substep 1412, an initial input query from the user is analyzed and a response to the input query is generated. Substep 1412 may also generate paths 1401 and 1402 as potential next steps. Each path may include a follow up question. The follow up questions are suggested paths that the user may select as next steps following the initial input query. The paths may be presented to the user as suggestions. The user may also decide to enter their own follow up question. For example, path 1401 may recommend/suggest follow up question “who sent the error message?” and path 1402 may recommend/suggest follow up question “when was the error message sent?” An expert user may review the recommended follow up questions and decide to manually enter a follow up question “What power state am I in now?” In decide subset 1414, the user selects a path to take where selecting a path includes submitting the follow up question corresponding to the path to the debug tool. Alternatively, the user may manually enter their own follow up question instead of selecting one of the recommended questions. In one embodiment, selecting a path may include clicking on a submit icon corresponding to the selected path in a graphical user interface if selecting one of the suggested follow up questions. In another embodiment, a new path After the user selects a path, step 1410 is complete.

After completion of step 1410, workflow 1400 continues to step 1420, which may depend on the path selected by the user in the previous step 1410. If the user selects path 1401, then step 1420 will include substeps 1422 and 1424. Alternatively, if path 1402 is selected, then step 1420 will include substeps 1426 and 1428. Substep 1422 is a detect substep similar to detect subset 1412 except that instead of analyzing an input query, substep 1422 analyzes the follow up question corresponding to path 1401 and generates a response to the question. Subset 1422 may also generate paths 1403 and 1404 as potential next steps where each path includes a follow up question to the question corresponding to path 1401. The follow up questions are suggested paths that the user may select as next steps. At substep 1424, the user may select path 1403 or path 1404 as the next question to submit to the debug tool. This process may iteratively repeat until the user has successfully debugged the problem as shown by substeps 1426, 1428, 1432, 1434, 1436, 1438, 1440, and 1444. As shown in workflow 1400, the number of paths presented to the user may not be fixed. For example, detect substep 1426 generates two paths that the user may select from while detect substep 1422 generates two paths that the user may select from. In one embodiment, workflow 1400 may be automated by having the workflow automatically decide on the path with the highest confidence score. For example, decide substep 1414 may automatically select path 1402 since the follow up question (i.e. predicted next query) corresponding to path 1402 has a higher confidence score than the follow up question corresponding to path 1401. Then at decide substep 1428, the workflow may automatically select path 1406 since the follow up question corresponding to path 1406 has a higher confidence score than the follow up questions corresponding to paths 1405 and 1407. This process of automatically submitting a follow up question with the highest confidence score may allow the debug tool to automatically debug the problem for the user. The user may passively review the follow up questions being submitted by the debug tool and intervene when appropriate. Intervention may occur when the user has reviewed sufficient information to successfully debug the problem or may occur when the user believes the debug tool has taken the questioning in a direction that is not adding value to the debug process.

FIG. 15 illustrates a graphical user interface for a debug tool according to an embodiment. As shown, GUI 1500 includes dialog box 1512. Dialog box 1512 is configured to receive input from the user. The input received by the user is the initial input query. Dialog box 1514 is configured to present the response to the initial input query. Dialog box 1522 is configured to present the most frequent next user question, which is also known as the predicted next input query with the highest confidence score. Dialog box 1524 is configured to present the response to the question presented in dialog box 1522. Dialog box 1532 is configured to present the second more frequent next user question, which is also known as the predicted next input query with the second highest confidence score. Dialog box 1534 is configured to present the response to the question presented in dialog box 1532. The questions presented in dialog boxes 1522 and 1532 are possible paths that the user may select as the use continues the conversation session. If the user wishes to continue by asking the question presented in dialog box 1522, the user may click on button 1526. Clicking on button 1526 may move the question in dialog box 1522 to dialog box 1512 as well as move the response in dialog box 1524 to dialog box 1514. Then GUI 1500 may present the next follow up questions and responses in dialog boxes 1522, 1524, 1532, and 1534. Similarly, if the user wishes to continue by asking the question presented in dialog box 1532, the user may click button 1536. In other embodiments, the dialog boxes may be arranged differently in GUI 1500 however each arrangement will include the dialog boxes for the current question, the current response, and predicted follow up question(s) and response(s).

FIG. 16 illustrates a flowchart for a generative AI-based tool according to one embodiment. Flowchart 1600 can may be implemented in computer readable code and executed by a processor within a computer system. Flowchart 1600 begins by receiving an input query from a user prompt at 1610. The input query can be in natural language and provided by a user debugging a problem with a system. In one example, the input query may be a question. In another example, the input query may be a command. Flowchart 1600 continues by determining a data source that contains debug data to answer the input query at 1620. In one embodiment, determining the data source can include converting the input query into a data query. For example, an input query such as “Please provide the error message” may be converted to the data query “ERROR_MESSAGE.” In one embodiment, determining the data source can include providing the data query or the input query to a query LLM to determine which data source from the many data sources stores the debug data corresponding to the query.

Once the data source has been determined, flowchart 1600 continues by retrieving the debug data from the data source at 1630. In one embodiment, retrieving the debug data can be assigned to an agent associated with the data source. The agent may in turn generate a parsing function to retrieve the debug data from the data source. In one example, the agent may include a LLM configured to receive the data query or debug data requested as an input variable and generate the parsing function to retrieve the debug data. Since each data source may have a different structure, each agent may have its own LLM configured for data retrieval from its corresponding data source.

Flowchart 1600 then continues by performing a lookup on a vectorized database to retrieve a plurality of entries at 1640. The vectorized database may be configured to past conversation sessions and performing the look up may include returning the top N entries from the vectorized database that are most similar to the current conversation context. The current conversation context may include one or more of the following: the input query from the user prompt, the debug data for responding to the input query, other queries submitted in the current conversation session, and other responses corresponding to the other queries. Flowchart 1600 then continues by generating a prompt based on the plurality of entries at 1650. The generated prompt may then be sent to a LLM at 1660 and one or more follow up questions may be received from the LLM at 1670. Flowchart 1600 may then continue by presenting the debug data as a response to the input query and the one or more follow up questions as suggestions for the next input query at 1680. In some embodiments, the responses to the follow up questions may also be presented so that the user can review possible follow up questions along with their answers/responses when deciding which path to take in the debug process.

FIG. 17 depicts a simplified block diagram of an example computer system, which can be used to implement some of the techniques described in the foregoing disclosure. As shown in FIG. 17, system 1700 includes one or more processors 1702 that communicate with several devices via one or more bus subsystems 1704. These devices may include a storage subsystem 1706 (e.g., comprising a memory subsystem 1708 and a file storage subsystem 1710) and a network interface subsystem 1716. Some systems may further include user interface input devices and/or user interface output devices (not shown).

Bus subsystem 1704 can provide a mechanism for letting the various components and subsystems of system 1700 communicate with each other as intended. Although bus subsystem 1704 is shown schematically as a single bus, alternative embodiments of the bus subsystem can utilize multiple buses.

Network interface subsystem 1716 can serve as an interface for communicating data between system 1700 and other computer systems or networks. Embodiments of network interface subsystem 1716 can include, e.g., Ethernet, a Wi-Fi and/or cellular adapter, a modem (telephone, satellite, cable, etc.), and/or the like.

Storage subsystem 1706 includes a memory subsystem 1708 and a file/disk storage subsystem 1710. Subsystems 1708 and 1710 as well as other memories described herein are examples of non-transitory computer-readable storage media that can store executable program code and/or data that provide the functionality of embodiments of the present disclosure.

Memory subsystem 1708 comprise one or more memories including a main random access memory (RAM) 1718 for storage of instructions and data during program execution and a read-only memory (ROM) 1720 in which fixed instructions are stored. File storage subsystem 1710 can provide persistent (e.g., non-volatile) storage for program and data files, and can include a magnetic or solid-state hard disk drive, an optical drive along with associated removable media (e.g., CD-ROM, DVD, Blu-Ray, etc.), a removable flash memory-based drive or card, and/or other types of storage media known in the art.

It should be appreciated that system 1700 is illustrative and many other configurations having more or fewer components than system 1700 are possible.

The above description illustrates various embodiments of the present invention along with examples of how aspects of the present invention may be implemented. The above examples and embodiments should not be deemed to be the only embodiments and are presented to illustrate the flexibility and advantages of the present invention as defined by the following claims. Based on the above disclosure and the following claims, other arrangements, embodiments, implementations and equivalents will be evident to those skilled in the art and may be employed without departing from the spirit and scope of the invention as defined by the claims.

### Further Examples

Each of the following non-limiting features in the following examples may stand on its own or may be combined in various permutations or combinations with one or more of the other features in the examples below. Embodiments of the present disclosure may include systems, circuits, and methods.

The above description illustrates various embodiments along with examples of how aspects of some embodiments may be implemented. The above examples and embodiments should not be deemed to be the only embodiments, and are presented to illustrate the flexibility and advantages of some embodiments as defined by the following claims. Based on the above disclosure and the following claims, other arrangements, embodiments, implementations, and equivalents may be employed without departing from the scope hereof as defined by the claims.

In some embodiments, a method, comprising receiving, in a user prompt of a graphical user interface, a question in a natural language, converting the question into a first data query, determining that a first data source from a plurality of data sources contains first debug data associated with the first data query, retrieving the first debug data from the first data source, adding the question and the first debug data to a current conversation session, performing a lookup on the vectorized database to retrieve a plurality of entries that are relevant to the current conversation session, generating a prompt from the plurality of entries, sending the prompt to a Large Language Model (LLM), receiving, from the LLM, a generated output corresponding to the prompt, the generated output including a follow up question in the natural language, and presenting, in the graphical user interface, the first debug data as a response to the question and the follow up question as a suggested debug path.

In one embodiment, the method further includes converting the follow up question into a second data query, determining a second data source from the plurality of data sources that contains second debug data corresponding to the second data query, retrieving the second debug data from the second data source, and presenting, in the graphical user interface, the second debug data as a response to the follow up question.

In one embodiment, the method further includes receiving, in the graphical user interface, a selection of the follow up question, adding the follow up question and the second debug data to the current conversation session, and updating the vectorized database to include current conversation session.

In one embodiment, determining that a first data source from a plurality of data sources contains first debug data associated with the first data query includes providing the first data query to a data source LLM, wherein the output generated by the data source LLM is the first data source.

In one embodiment, the method further includes updating the vectorized database to include the current conversation session.

In one embodiment, retrieving the first debug data from the first data source includes: providing the first debug data to an agent LLM, receiving, from the agent LLM, a parsing function, and processing the parsing function to retrieve the first debug data from the first data source.

In one embodiment, each entry in the plurality of entries is associated with a unique previous conversation session and the plurality of entries are previous conversation sessions that are similar to the current conversation session.

In one embodiment, the generated output includes a plurality of follow up questions, one of which is the follow up question.

In one embodiment, the method further includes generating a confidence score for each of the plurality of follow up questions, selecting a subset of the plurality of follow up questions based on the confidence score, and presenting, in the graphical user interface, the subset of follow up questions.

In some embodiments, a system, comprising one or more processors, non-transitory computer-readable medium storing a program executable by the one or more processors, the program comprising sets of instructions for: receiving, in a user prompt of a graphical user interface, a question in a natural language, converting the question into a first data query, determining that a first data source from a plurality of data sources contains first debug data associated with the first data query, retrieving the first debug data from the first data source, adding the question and the first debug data to a current conversation session, performing a lookup on the vectorized database to retrieve a plurality of entries that are relevant to the current conversation session, generating a prompt from the plurality of entries, sending the prompt to a Large Language Model (LLM), receiving, from the LLM, a generated output corresponding to the prompt, the generated output including a follow up question in the natural language, and presenting, in the graphical user interface, the first debug data as a response to the question and the follow up question as a suggested debug path.

In some embodiments, a non-transitory computer-readable medium stores a program executable by one or more processors, the program comprises sets of instructions for: receiving, in a user prompt of a graphical user interface, a question in a natural language, converting the question into a first data query, determining that a first data source from a plurality of data sources contains first debug data associated with the first data query, retrieving the first debug data from the first data source, adding the question and the first debug data to a current conversation session, performing a lookup on the vectorized database to retrieve a plurality of entries that are relevant to the current conversation session, generating a prompt from the plurality of entries, sending the prompt to a Large Language Model (LLM), receiving, from the LLM, a generated output corresponding to the prompt, the generated output including a follow up question in the natural language, and presenting, in the graphical user interface, the first debug data as a response to the question and the follow up question as a suggested debug path.

What is claimed is:

1. A method, comprising:
receiving, in a user prompt of a graphical user interface, a question in a natural language;
converting the question into a first data query;
determining that a first data source from a plurality of data sources contains first debug data associated with the first data query;
retrieving the first debug data from the first data source;
adding the question and the first debug data to a current conversation session;
performing a lookup on the vectorized database to retrieve a plurality of entries that are relevant to the current conversation session;
generating a prompt from the plurality of entries;
sending the prompt to a Large Language Model (LLM);
receiving, from the LLM, a generated output corresponding to the prompt, the generated output including a follow up question in the natural language; and
presenting, in the graphical user interface, the first debug data as a response to the question and the follow up question as a suggested debug path.

2. The method of claim 1, further comprising:
converting the follow up question into a second data query;
determining a second data source from the plurality of data sources that contains second debug data corresponding to the second data query;
retrieving the second debug data from the second data source; and
presenting, in the graphical user interface, the second debug data as a response to the follow up question.

3. The method of claim 2, further comprising:
receiving, in the graphical user interface, a selection of the follow up question;
adding the follow up question and the second debug data to the current conversation session; and
updating the vectorized database to include current conversation session.

4. The method of claim 1, wherein determining that a first data source from a plurality of data sources contains first debug data associated with the first data query includes providing the first data query to a data source LLM, wherein the output generated by the data source LLM is the first data source.

5. The method of claim 1, further comprising updating the vectorized database to include the current conversation session.

6. The method of claim 1, wherein retrieving the first debug data from the first data source includes:
providing the first debug data to an agent LLM;
receiving, from the agent LLM, a parsing function; and
processing the parsing function to retrieve the first debug data from the first data source.

7. The method of claim 1, wherein each entry in the plurality of entries is associated with a unique previous conversation session and the plurality of entries are previous conversation sessions that are similar to the current conversation session.

8. The method of claim 7, wherein the generated output includes a plurality of follow up questions, one of which is the follow up question.

9. The method of claim 8, further comprising:
generating a confidence score for each of the plurality of follow up questions;
selecting a subset of the plurality of follow up questions based on the confidence score; and
presenting, in the graphical user interface, the subset of follow up questions.

10. A system comprising:
one or more processors;
a non-transitory computer-readable medium storing a program executable by the one or more processors, the program comprising sets of instructions for:
receiving, in a user prompt of a graphical user interface, a question in a natural language;
converting the question into a first data query;
determining that a first data source from a plurality of data sources contains first debug data associated with the first data query;
retrieving the first debug data from the first data source;
adding the question and the first debug data to a current conversation session;
performing a lookup on the vectorized database to retrieve a plurality of entries that are relevant to the current conversation session;
generating a prompt from the plurality of entries;
sending the prompt to a Large Language Model (LLM);
receiving, from the LLM, a generated output corresponding to the prompt, the generated output including a follow up question in the natural language; and
presenting, in the graphical user interface, the first debug data as a response to the question and the follow up question as a suggested debug path.

11. The system of claim 10, wherein the program further comprises sets of instructions for:
converting the follow up question into a second data query;
determining a second data source from the plurality of data sources that contains second debug data corresponding to the second data query;
retrieving the second debug data from the second data source; and
presenting, in the graphical user interface, the second debug data as a response to the follow up question.

12. The system of claim 11, wherein the program further comprises sets of instructions for:
receiving, in the graphical user interface, a selection of the follow up question;
adding the follow up question and the second debug data to the current conversation session; and
updating the vectorized database to include current conversation session.

13. The system of claim 10, wherein each entry in the plurality of entries is associated with a unique previous conversation session.

14. The system of claim 13, wherein the generated output includes a plurality of follow up questions, one of which is the follow up question.

15. The system of claim 14, the program further comprises sets of instructions for:
generating a confidence score for each of the plurality of follow up questions;
selecting a subset of the plurality of follow up questions based on the confidence score; and
presenting, in the graphical user interface, the subset of follow up questions.

16. A non-transitory computer-readable medium storing a program executable by one or more processors, the program comprising sets of instructions for:
receiving, in a user prompt of a graphical user interface, a question in a natural language;
converting the question into a first data query;
determining that a first data source from a plurality of data sources contains first debug data associated with the first data query;
retrieving the first debug data from the first data source;
adding the question and the first debug data to a current conversation session;
performing a lookup on the vectorized database to retrieve a plurality of entries that are relevant to the current conversation session;
generating a prompt from the plurality of entries;
sending the prompt to a Large Language Model (LLM);
receiving, from the LLM, a generated output corresponding to the prompt, the generated output including a follow up question in the natural language; and
presenting, in the graphical user interface, the first debug data as a response to the question and the follow up question as a suggested debug path.

17. The non-transitory computer-readable medium of claim 16, wherein the program further comprising sets of instructions for:
converting the follow up question into a second data query;
determining a second data source from the plurality of data sources that contains second debug data corresponding to the second data query;
retrieving the second debug data from the second data source; and
presenting, in the graphical user interface, the second debug data as a response to the follow up question.

18. The non-transitory computer-readable medium of claim 17, wherein the program further comprises sets of instructions for:
receiving, in the graphical user interface, a selection of the follow up question;
adding the follow up question and the second debug data to the current conversation session; and
updating the vectorized database to include current conversation session.

19. The non-transitory computer-readable medium of claim 18, wherein the generated output includes a plurality of follow up questions, one of which is the follow up question.

20. The non-transitory computer-readable medium of claim 16, wherein program further comprises sets of instructions for:
generating a confidence score for each of the plurality of follow up questions;
selecting a subset of the plurality of follow up questions based on the confidence score; and
presenting, in the graphical user interface, the subset of follow up questions.
